(19) United States
(12) Patent Application Publication
(10) Pub. No.: US 2010/0109511 A1
(43) Pub. Date: May 6, 2010

(54) ORGANIC LIGHT EMITTING DISPLAY AND METHOD OF MANUFACTURING THE SAME

(76) Inventors: Seong-Ho KIM, Yongin-si (KR); Beohm-Rock Choi, Seoul (KR); Young-Rok Song, Yongin-si (KR)

Correspondence Address: Haynes and Boone, LLP;IP Section, 2323 Victory Avenue, SUITE 700, Dallas, TX, 75219, US

(21) Appl. No.: 12/421,506

(22) Filed: Apr. 9, 2009

(30) Foreign Application Priority Data
Oct. 31, 2008 (KR) 2008-107853

(51) Int. Cl. H01J 1/62; H01L 51/56

(52) U.S. Cl. 313/504; 438/34; 257/E51.022

(57) ABSTRACT

An organic light emitting display and a method for manufacturing the same are provided in one or more embodiments. For example, an organic light emitting display may include a first substrate including a plurality of main-pixel areas each of which may include a plurality of sub-pixel areas and an insulating layer pattern arranged on the first substrate. The insulating layer pattern may include an inclined surface having an inclination angle with respect to the first substrate and corresponding to each sub-pixel area. A first electrode may be arranged on the inclined surface, an organic light emitting layer may be arranged on the first electrode, and a second electrode may be arranged on the organic light emitting layer.

### CROSS-REFERENCE TO RELATED APPLICATION

This application relies for priority upon Korean Patent Application No. 2008-107853 filed on Oct. 31, 2008, the contents of which are herein incorporated by reference in their entirety.

### BACKGROUND

1. Technical Field

The present disclosure relates generally to an organic light emitting display capable of displaying a plurality of images and a method of manufacturing the organic light emitting display.

2. Related Art

In general, an organic light emitting display (OLED) includes a substrate, an anode arranged on the substrate, an emission layer arranged on the anode, and a cathode arranged on the emission layer. When a voltage is applied to the anode and the cathode, holes and electrons are injected into the emission layer, and the injected holes and electrons are recombined with each other in the emission layer, so that excitons are generated. The emission layer emits light using an energy generated when the excitons transition from an excited state to a ground state. Such OLEDs have attracted attention as a next generation flat panel display since the OLED provides certain advantages, such as wide viewing angle, fast response time, and high resolution.

### SUMMARY

One or more embodiments provide an organic light emitting display capable of displaying a plurality of images.

One or more embodiments also provide a method of manufacturing the organic light emitting display.

In an example embodiment, an organic light emitting display may include a first substrate including a plurality of main-pixel areas each of which may include a plurality of sub-pixel areas and an insulating layer pattern arranged on the first substrate. The insulating layer pattern may include an inclined surface having an inclination angle with respect to the first substrate to correspond to each sub-pixel. A first electrode may be arranged on the inclined surface, an organic light emitting layer may be arranged on the first electrode, and a second electrode may be arranged on the organic light emitting layer.

The organic light emitting layer may be inclined with respect to the first substrate depending on an inclination angle between the inclined surface and the first substrate, and thus most of the lights generated from the organic light emitting layer proceed or are transmitted in a direction inclined with respect to the first substrate. Therefore, in embodiments in which the insulating layer pattern includes a plurality of inclined surfaces inclined in directions different from each other, the organic light emitting display may display images in different viewing angles using the light exiting in different directions.

In another aspect, a method of manufacturing the organic light emitting display may be provided as follows. A first substrate may be prepared to include a plurality of main-pixel areas each of which may include a plurality of sub-pixel areas, an insulating layer pattern having an inclined surface inclined with respect to the first substrate and corresponding to each of the sub-pixel areas may be formed on the first substrate, a first electrode may be formed on the inclined surface, an organic light emitting layer may be formed on the first electrode, and a second electrode may be formed on the organic light emitting layer

The insulating layer pattern having the inclined surface may be formed using an imprint method. Also, the insulating layer pattern may be formed by forming a preliminary insulating layer pattern having a step difference and reflowing the preliminary insulating layer pattern using a heat process.

According to the above, the organic light emitting display may display a plurality of images using light that proceeds in different directions corresponding to respective inclined surfaces.

### BRIEF DESCRIPTION OF THE DRAWINGS

The above embodiments and other aspects of the present disclosure will become readily apparent by reference to the following detailed description when considered in conjunction with the accompanying drawings wherein:

FIG. 1 is a plan view showing an organic light emitting display in accordance with one or more embodiments;

FIG. 2 is an exploded perspective view showing an organic light emitting display in accordance with one or more embodiments;

FIG. 3 is a cross-sectional view taken along a line I-I′ of FIG. 2 in accordance with an embodiment;

FIG. 4 is a view showing a viewing angle of an organic light emitting display in accordance with one or more embodiments;

FIG. 5 is a circuit diagram showing an organic light emitting display in accordance with one or more embodiments;

FIGS. 6 to 8 are sectional views showing a manufacturing method of an organic light emitting display of FIG. 3 in accordance with one or more embodiments; and

FIGS. 9 and 10 are sectional views showing a manufacturing method of an organic light emitting display of FIG. 3 in accordance with one or more embodiments.

### DETAILED DESCRIPTION

It will be understood that when an element or layer is referred to as being “on”, “connected to” or “coupled to” another element or layer, it may be directly on, connected or coupled to the other element or layer or there may be intervening elements or layers present. In contrast, when an element is referred to as being “directly on,” “directly connected to” or “directly coupled to” another element or layer, there are no intervening elements or layers present. Like numbers refer to like elements throughout. As used herein, the term “and/or” may include any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present disclosure will be explained in detail with reference to the accompanying drawings.

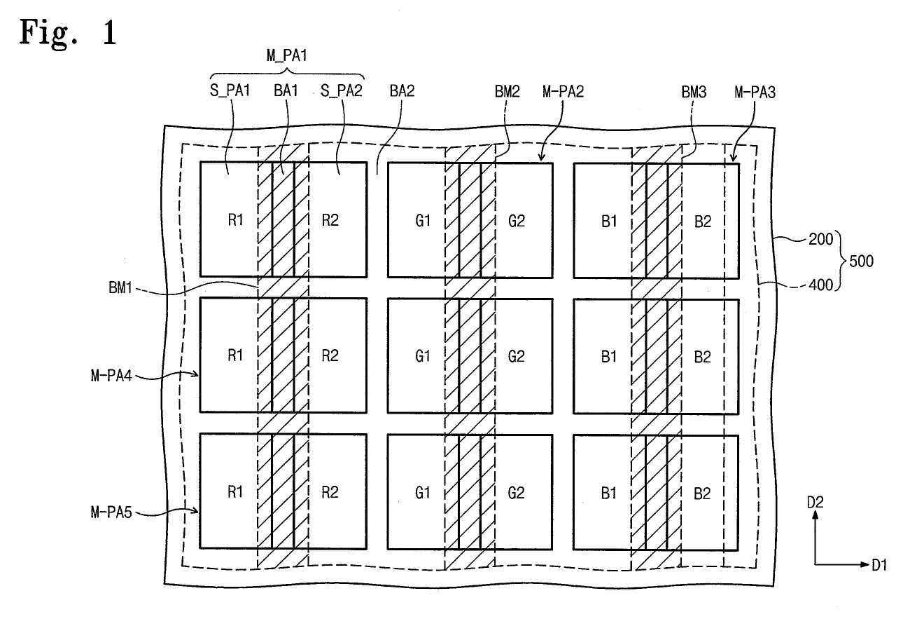

FIG. 1 is a plan view showing an organic light emitting display in accordance with one or more embodiments. In the present embodiment, for example, a display substrate for the organic light emitting display may include a plurality of pixels, however, since the pixels have the same structure and function, some parts of the pixels will be described in FIG. 1, and thus others will be omitted.

Referring to FIG. 1, an organic light emitting display (OLED) 500 may include a display substrate 200 and an opposite substrate 400. The display substrate 200 may include a plurality of main-pixel areas. Two main-pixel areas adjacent to each other may be spaced apart from each other while interposing a second boundary area BA2 therebetween, and each main-pixel area may include two sub-color pixels that are spaced apart from each other.

Light exiting to an exterior after passing through the two sub-color pixels arranged in one main-pixel area have the same color. For instance, a first main-pixel area M_PA1 may include a first sub-pixel area S_PA1 and a second sub-pixel area S_PA2 spaced apart from the first sub-pixel area S_PA1 while interposing a first boundary area BA1 between the first and second sub-pixel areas S_PA1 and S_PA2, and a first red color pixel RI and a second red color pixel R2, which are arranged in the first sub-pixel area S_PA1 and the second sub-pixel area S_PA2, respectively, generate red light.

Meanwhile, a second main-pixel area M_PA2 may include two sub-pixel areas, and a first green color pixel G1 and a second green color pixel G2 may be arranged in the two sub-pixel areas, respectively, to generate green light. In addition, a third main-pixel area M_PA3 may include two sub-pixel areas, and a first blue color pixel B1 and a second blue color pixel B2 may be arranged in the two sub-pixel areas, respectively, to generate blue light.

The main-pixel areas may be arranged in a matrix configuration along a row direction as a first direction D1 and a column direction as a second direction D2 substantially perpendicular to the first direction D1. For instance, in a row including the first main-pixel area M_PA1, the first main-pixel area M_PA1 generating the red light, the second main-pixel area M-PA2 generating the green light, and the third main-pixel area M_PA3 generating the blue light may be sequentially arranged along the first direction D1. That is, in any row of the matrix configuration of the main-pixel areas, two adjacent main-pixel areas in the first direction D1 may generate different colors of light from each other.

In addition, in a column including the first main-pixel area M_PA1, the first main-pixel area M_PA1 generating red light, a forth main-pixel area M_PA4 generating red light, and a fifth main-pixel area M_PA5 generating red light may be sequentially arranged along the second direction D2. That is, in any column of the matrix configuration of the main-pixel areas, color pixels of the main-pixel areas arranged in one column may generate the same color.

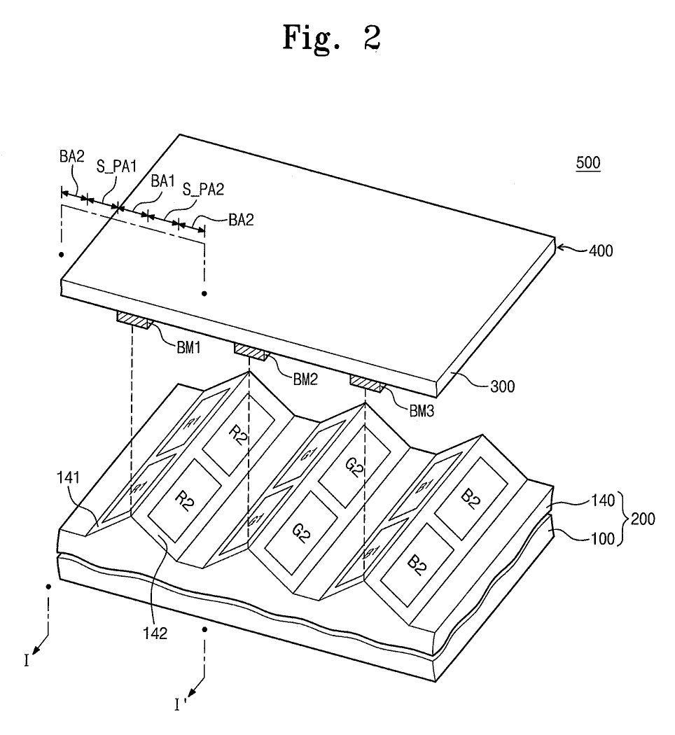

The opposite substrate 400 may be coupled with the display substrate 200 to face the display substrate 200. The opposite substrate 400 may include a second substrate 300 (shown in FIG. 2) and a plurality of light blocking layers arranged on the second substrate 300. The light blocking layers include a metal material, such as chromium, magnesium, or the like, to block the light.

The light blocking layers may include a first light blocking layer BM1, a second light blocking layer BM2, and a third light blocking layer BM3. The first to third light blocking layers BM1, BM2, and BM3 may be spaced apart from each other and may extend in the second direction D2. Each of the first to third light blocking layers BM1, BM2, and BM3 may overlap main-pixel areas arranged in the second direction D2. For instance, the first light blocking layer BM1 may overlap the first main-pixel area M_PA1, the fourth main-pixel area M_PA4, and the fifth main-pixel area M_PA5 that are arranged in the column including the first main-pixel area M_PA1. More particularly, the first light blocking layer BM1 may mainly overlap the first boundary area BA1, a boundary area between two red color pixels R1 and R2 arranged in the fourth main-pixel area M_PA4, and a boundary area between two red color pixels R1 and R2 arranged in the fifth main-pixel area M_PA5.

The first to third light blocking layers BM1, BM2, and BM3 may block light that proceed in or are transmitted in a certain direction among lights generated from the main-pixel areas. For example, transmission directions of the light generated from the first red color pixel R1 and the second red color pixel R2 arranged in the first sub-pixel area S_PA1 and the second sub-pixel area S_PA2, respectively, may be decided at random, however, the first light blocking layer BM1 may prevent the light generated from the first and second red color pixels R1 and R2 from exiting to the exterior through the first boundary area BA1. Thus, although the first and second red color pixels R1 and R2 generate light having the same color, the mixture of the red light generated from the first red color pixel R1 and the red light generated from the second red color pixel R2 may be prevented from exiting outward.

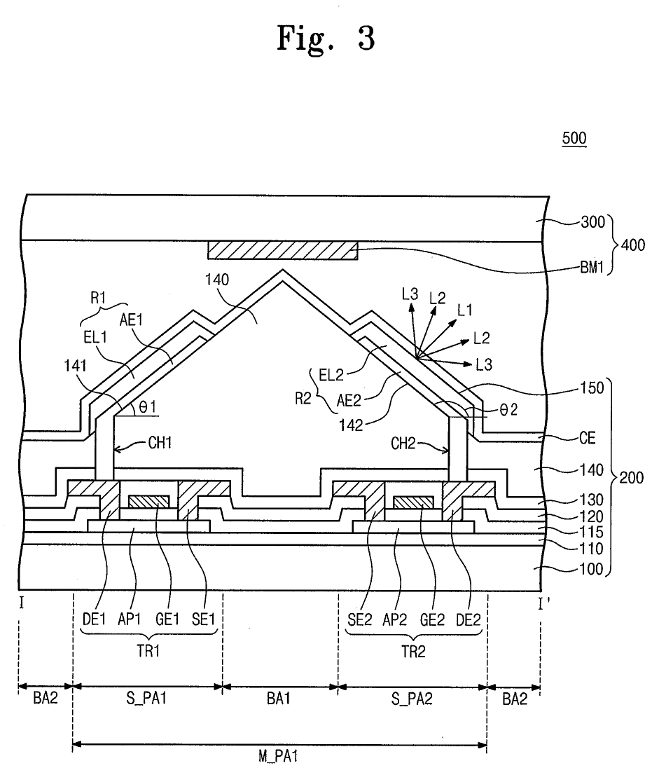

FIG. 2 is an exploded perspective view showing the organic light emitting display in accordance with one or more embodiments, and FIG. 3 is a cross-sectional view taken along a line I-I′ of FIG. 2 in accordance with an embodiment. FIG. 2 shows the color pixels inclined with respect to the first substrate 100.

Referring to FIGS. 2 and 3, the display substrate 200 may include a first substrate 100, the first red color pixel R1 arranged in the first sub-pixel area S_PA1 of the first substrate 100, a first driving transistor TR1 electrically connected to the first red color pixel R1, the second red color pixel R2 arranged in the second sub-pixel area S_PA2 of the first substrate 100, and a second driving transistor TR2 electrically connected to the second red color pixel R2.

A blocking layer 110 may be arranged on the first substrate 100. The blocking layer 110 may include an insulating material, such as silicon oxide or silicon nitride, to prevent ions eluted from the first substrate 100 from being diffused toward other elements arranged on the first substrate 100.

In the present embodiment, for example, the first driving transistor TR1 may be a polysilicon type thin film transistor, and the first driving transistor TR1 may be electrically connected to the first red color pixel R1 to switch a power voltage that drives the first red color pixel R1.

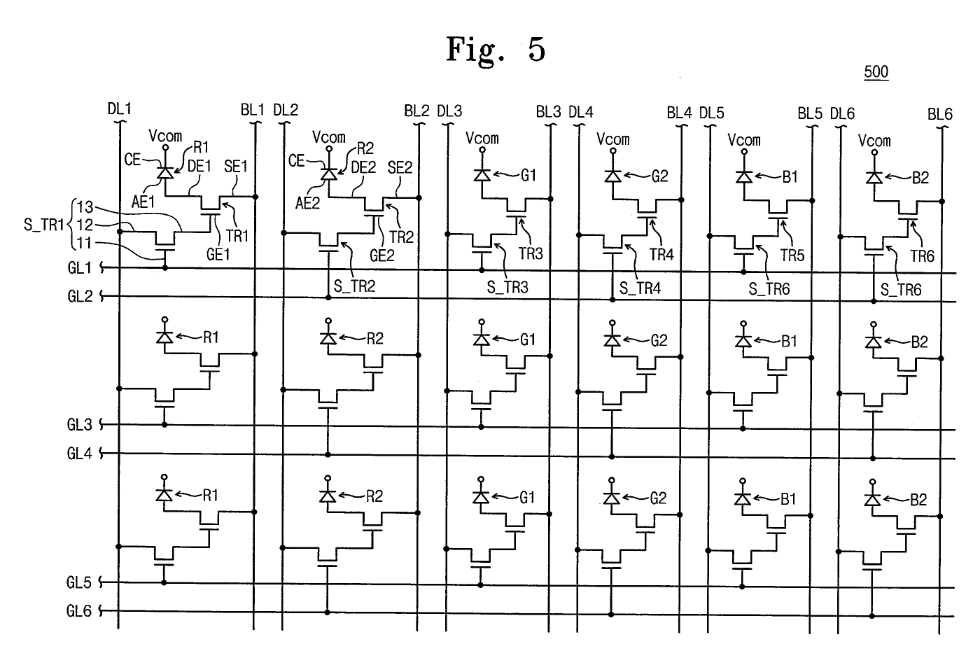

The first driving transistor TR1 may include a first gate electrode GE1, a first source electrode SE1, a first drain electrode DE1, and a first active pattern AP1. Also, the first driving transistor TR1 may be electrically connected to a first switching transistor S_TRL (shown in FIG. 5), and an operation of the first driving transistor TR1 may be switched by the first switching transistor S_TR1.

The first active pattern AP1 may include a semiconductor material, such as polysilicon, and the first active pattern AP1 may be arranged on the blocking layer 110. Also, the first gate electrode GE1 may be arranged on the first active pattern AP1 while interposing a gate insulating layer 115 therebetween, and the first gate electrode GE1 may be electrically connected to a drain electrode 13 (shown in FIG. 5) of the first switching transistor S_TRL (shown in FIG. 5). An inter-insulating layer 120 may be arranged on the first gate electrode GE1, and the gate insulating layer 115 and the inter-insulting layer 120 may be partially removed such that the first source electrode SE1 and the first drain electrode DE1 make contact with the first active pattern AP1.

The first source electrode SE1 may branch from a first power voltage line BL1 (shown in FIG. 5) and may receive the power voltage from the first power voltage line BL1. Thus, when the first driving transistor TR1 is turned on by the first switching transistor S_TR1, the power voltage provided from the first power voltage line BL1 may be applied to the first drain electrode DE1 from the first source electrode SE1 through the first active pattern AP1.

The second driving transistor TR2 may include a second gate electrode GE2, a second source electrode SE2, a second drain electrode DE2, and a second active pattern AP2. As the first driving transistor TR1 switches the power voltage provided to the first red color pixel R1, the second driving transistor TR2 switches the power voltage provided to the second red color pixel R2 that is electrically connected to the second driving transistor TR2.

The second gate electrode GE2 may be electrically connected to a drain electrode of a second switching transistor S_TR2 (shown in FIG. 5), and the second source electrode SE2 may branch from a second power voltage line BL2 (shown in FIG. 5). Thus, when the second driving transistor TR2 is turned on by the second switching transistor S_TR2, the power voltage provided from the second power voltage line BL2 may be applied to the second drain electrode DE2 from the second source electrode SE2 through the second active pattern AP2.

As described above, the switching transistor controlling the operation of the first driving transistor TR1 may be different from the switching transistor controlling the operation of the second driving transistor TR2. Therefore, the power voltage used to drive the first red color pixel R1 and the power voltage used to drive the second red color pixel R2 may be individually controlled. More detailed descriptions of the individual control to the color pixels will be described with reference to FIG. 5.

A protective layer 130 may be arranged on the first and second driving transistors TR1 and TR2 to protect the first and second driving transistors TR1 and TR2 from external impacts. An insulating layer pattern 140 may be arranged on the protective layer 130. The insulating layer pattern 140 may include a first inclined surface 141 and a second inclined surface 142. More particularly, when viewed in cross-sectional, a thickness of the insulating layer pattern 140 may gradually decrease from the first boundary area BA1 to the first sub-pixel area S_PA1 to define the first inclined surface 141, and the thickness of the insulating layer pattern 140 may gradually decrease from the first boundary area BA1 to the second sub-pixel area S_PA2 to define the second inclined surface 142.

Thus, the insulating layer pattern 140 may have a maximum thickness in the first boundary area BA1, and as a result, the insulating layer pattern 140 may have a mountain shape corresponding to the first boundary area BA1. In addition, the insulating layer pattern 140 may have a minimum thickness in the second boundary area BA2, and thus, the insulating layer pattern 140 may have a valley shape corresponding to the second boundary area BA2.

When an angle between the first inclined surface 141 and the first substrate 100 is referred to as a first angle θ1 and an angle between the second inclined surface 142 and the first substrate 100 is referred to as a second angle θ2, the first angle θ1 may be about 10 degrees to about 80 degrees and the second angle θ2 may be about 100 degrees to about 170 degrees.

The protective layer 130 and the insulating layer pattern 140 may be partially removed to form a first contact hole CH1 and a second contact hole CH2 therethrough. A first positive electrode AE1 may be arranged in the first contact hole CH1, and a second positive electrode AE2 may be arranged in the second contact hole CH2. Also, the first positive electrode AE1 may be electrically connected to the first drain electrode DE1 and arranged in the first inclined surface 141, and the second positive electrode AE2 may be electrically connected to the second drain electrode DE2 and arranged in the second inclined surface 142.

A first organic light emitting layer EL1 may be arranged on the first positive electrode AE1, and a second organic light emitting layer EL2 may be arranged on the second positive electrode AE2. Also, a negative electrode CE may be arranged on the first and second positive electrodes AE1 and AE2 to receive a common voltage Vcom (shown in FIG. 5). The first organic light emitting layer EL1 may generate red light using a current flowing between the first positive electrode AE1 and the negative electrode CE, and the second organic light emitting layer EL2 may generate red light using the current flowing between the second positive electrode AE2 and the negative electrode CE. The red lights generated from the first and second organic light emitting layers EL1 and EL2 may exit to an upper portion of the second substrate 300 after passing through the negative electrode CE.

Meanwhile, amounts of the lights generated from the first and second organic light emitting layers EL1 and EL2 may depend on the transmission directions of the lights. For instance, when assuming that a first light L1, a second light L2, and a third light L3 may be generated from the second organic light emitting layer EL2, the first light L1 proceeds or is transmitted in a direction at a right angle with respect to an upper surface 150 of the second organic light emitting layer EL2, the second light L2 proceeds or is transmitted in a direction at an angle of about 60 degrees to about 120 degrees with respect to the upper surface 150, and the third light L3 proceeds or is transmitted in a direction at an angle of about 30 degrees to about 150 degrees with respect to the upper surface 150, the amount of the second light L2 may be greater than the amount of the third light L3, and the amount of the first light L1 may be greater than the amount of the second light L2.

More particularly, the amount of the second light L2 may be about 87% of the amount of the first light L1, and the amount of the third light L3 may be about 50% of the amount of the first light L1. Although not shown in FIG. 3, the amount of the light generated from the second organic light emitting layer EL2 and proceeding or being transmitted in a direction at an angle of about 5 degrees to about 175 degrees with respect to the upper surface 150 may be about 9% of the amount of the first light L1. That is, the amount of the light emitted from the second organic light emitting layer EL2 increases as the angle between the upper surface 150 and the transmission direction may be closer to the right angle with respect to the upper surface 150.

Thus, when a user perceives the red light generated from the second red color pixel R2, the first light L1 may contribute more than the second light L2 and the third light L3 such that the user may perceive the red light generated from the second red color pixel R2. This means that a main viewing angle of the second red color pixel R2 may be determined according to the transmission direction of the first light L1. Meanwhile, as described above, the first light L1 proceeds or is transmitted at a right angle with respect to the upper surface 150, and an angle between the upper surface 150 and the first substrate 100 may depend upon an angle between the second inclined surface 142 and the first substrate 100. Therefore, the main viewing angle of the second red color pixel R2 may be adjusted by changing the second angle θ2 between the second inclined surface 142 and the first substrate 100.

Similar to the light emitted from the second organic light emitting layer EL2, an amount of the light emitted from the first organic light emitting layer EL1 increases as an angle between the upper surface of the first organic light emitting layer EL1 and the transmission direction may be closer to the right angle with respect to the upper surface of the first organic light emitting layer EL1. Thus, the main viewing angle of the first red color pixel R1 including the first organic light emitting layer EL1 may be adjusted by changing the first angle θ1 between the first inclined surface 141 and the first substrate 100.

The opposite substrate 400 may include the second substrate 300, and the first to third light blocking layers BM1, BM2, and BM3 that are arranged on the second substrate 300 to block the light. When viewed in a plan view, the first light blocking layer BM1 overlaps an area between the first red color pixel R1 and the second red color pixel R2 to block a portion of the lights generated from the first and second red color pixels R1 and R2, the second light blocking layer BM2 overlaps an area between the first green color pixel G1 and the second green color pixel G2 to block a portion of the lights generated from the first and second green color pixels G1 and G2, and the third light blocking layer BM3 overlaps an area between the first blue color pixel B1 and the second blue color pixel B2 to block a portion of the lights generated from the first and second blue color pixels B1 and B2.

In other words, the first light blocking layer BM1 may be arranged on the second substrate 300 corresponding to the first boundary area BA1. Thus, the first light blocking layer BM1 prevents the light generated from the first red color pixel R1 and the light generated from the second red color pixel R2 from being mixed with each other and exiting outward.

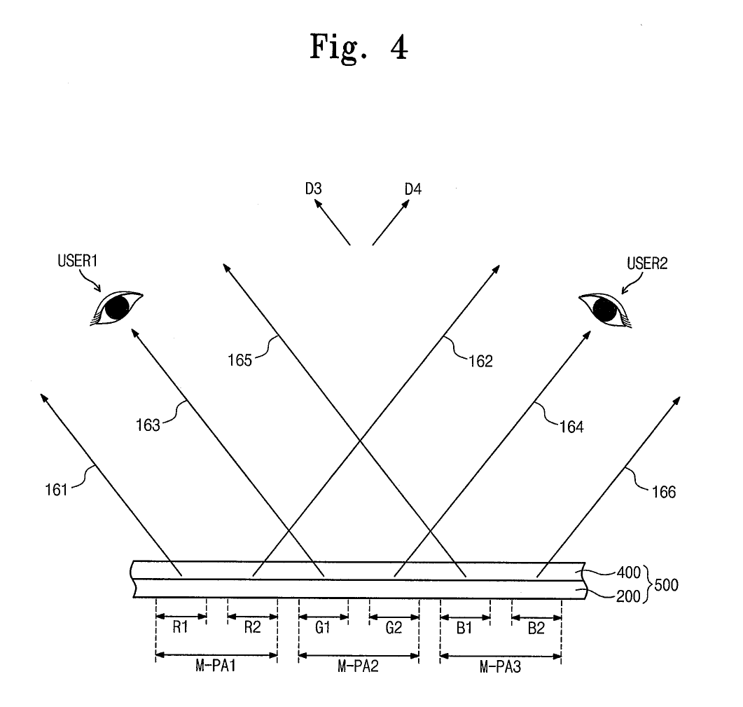

FIG. 4 is a view showing a viewing range of the organic light emitting display in accordance with one or more embodiments. FIG. 4 shows a viewing range of pixels arranged in the first row of FIG. 1.

Referring to FIGS. 1 and 4, the OLED 500 may generate a first red light 161 and a second red light 162 in the first main-pixel area M_PA1. More particularly, the first red color pixel R1 and the second red color pixel R2 arranged in the first main-pixel area M_PA1 may generate the first red light 161 and the second red light 162, respectively, the first green color pixel G1 and the second green color pixel G2 arranged in the second main-pixel area M_PA2 may generate a first green light 163 and a second green light 164, respectively, and the first blue color pixel B1 and the second blue color pixel B2 arranged in the third main-pixel area M_PA3 may generate a first blue light 165 and a second blue light 166, respectively.

As described above with reference to FIGS. 2 and 3, the two color pixels arranged in each of the first to third main-pixel areas M_PA1, M_PA2, and M_PA3 generate lights that may be transmitted in different directions from each other. When assuming that the first red light 161 is transmitted approximately in a third direction D3 and the second red light 162 is transmitted approximately in a fourth direction D4, the first green light 163 and the first blue light 165 are transmitted approximately in the third direction D3, and the second green light 164 and the second blue light 166 are transmitted approximately in the fourth direction D4.

When the lights generated from the OLED 500 proceed or are transmitted in two directions, the viewing range of the OLED 500 may be determined depending on the two directions only. For instance, when a first user USER1 and a second user USER2 perceive the lights generated from the OLED 500, the first user USER1 perceives the light in which the first red light 161, the first green light 163, and the first blue light 165 are mixed with each other, and the second user USER2 perceives the light in which the second red light 162, the second green light 164, and the second blue light 166 are mixed with each other. That is, the first and second users USER1 and USER2 perceive different lights according to their positions relative to the OLED 500. Thus, the first user USER1 perceives an image displayed by color pixels including the first red color pixel R1, the first green color pixel G1, and the first blue color pixel B1, and the second user USER2 perceives an image displayed by color pixels including the second red color pixel R2, the second green color pixel G2, and the second blue color pixel B2.

When the users perceive the different lights according to their positions, the OLED 500 may display the same image in two different main viewing angles from each other, or may display two different images in different main viewing angles from each other.

FIG. 5 is a circuit diagram showing the organic light emitting display in accordance with one or more embodiments. In FIG. 5, electrical connections among a plurality of first red color pixels R1, a plurality of second red color pixels R2, a plurality of first green color pixels G1, a plurality of second green color pixels G2, a plurality of first blue color pixels B1, and a plurality of second blue color pixels B2, which may be arranged in the display substrate 200 of FIG. 1, have been shown.

Referring to FIG. 5, in color pixels arranged in the first row, the OLED 500 may include first to sixth gate lines GL1, GL2, GL3, GL4, GL5, and GL6, first to sixth data lines DL1, DL2, DL3, DL4, DL5, and DL6, and first to sixth power voltage lines BL1, BL2, BL3, BL4, BL5, and BL6.

One of the first, second, third, fourth, fifth and sixth gate lines GL1, GL2, GL3, GL4, GL5 and GL6 and one of the first, second, third, fourth, fifth and sixth data lines DL1, DL2, DL3, DL4, DL5 and DL6 define a sub-pixel area with one of first to sixth power voltage lines BL1, BL2, BL3, BL4, BL5, and BL6.

For instance, the first gate line GL1 and the first data line DL1 may define the first sub-pixel area S_PA1 (shown in FIG. 1) with the first power voltage line BL1, and the second gate line GL2 and the second data line DL2 may define the second sub-pixel area S_PA2 (shown in FIG. 1) with the second power voltage line BL2. Also, the first sub-pixel area S_PA1 may include the first switching transistor S_TR1, the first driving transistor TR1, the first positive electrode AE1, and the negative electrode CE, and the second sub-pixel area S_PA2 may include the second switching transistor S_TR2, the second driving transistor TR2, the second positive electrode AE2, and the negative electrode CE.

The first switching transistor S_TR1 may include a gate electrode 11 electrically connected to the first gate line GL1, a source electrode 12 electrically connected to the first data line DL1, and the drain electrode 13. Also, the first driving transistor TR1 may include the first gate electrode GE1 electrically connected to the drain electrode 13, the first source electrode SE1 electrically connected to the first power voltage line BL1, and the first drain electrode DE1.

In the first switching transistor S_TR1 and the first driving transistor TR1, the first switching transistor S_TR1 may be turned on in response to a gate signal provided from the first gate line GL1. Thus, a data signal may be applied to the first gate electrode GE1 from the first data line DL1 through the source electrode 12 and the drain electrode 13 to turn on the first driving transistor TR1. When the first driving transistor TR1 is turned on by the data signal, the power voltage may be applied to the first positive electrode AE1 from the first power voltage line BL1 through the first source electrode SE1 and the first drain electrode DE1.

In the color pixels arranged in the first row, the first red color pixel R1 may be electrically connected to the first switching transistor S_TR1 and the first driving transistor TR1, the first green color pixel G1 may be electrically connected to a third switching transistor S_TR3 and a third driving transistor TR3, and the first blue color pixel B1 may be electrically connected to a fifth switching transistor S_TR5 and a fifth driving transistor TR5. The first, third, and fifth switching transistors S_TR1, S_TR3, and S_TR5 may be electrically connected to the first gate line GL1 and turned on upon receiving the gate signal provided from the first gate line GL1. Since switching operations of the first, third, and fifth driving transistors TR1, TR3, and TR5 correspond to switching operations of the first, third, and fifth switching transistors S_TR1, S_TR3, and S_TR5 in one-to-one correspondence, operations of the first red color pixel R1, the first green color pixel G1, and the first blue color pixel B1 may be controlled by the gate signal transmitted through the first gate line GL1.

Also, in the color pixels arranged in the first row, the second red color pixel R2 may be electrically connected to the second switching transistor S_TR2 and the second driving transistor TR2, the second green color pixel G2 may be electrically connected to a fourth switching transistor S_TR4 and a fourth driving transistor TR4, and the second blue color pixel B2 may be electrically connected to a sixth switching transistor S_TR6 and a sixth driving transistor TR6. The second, fourth, and sixth switching transistors S_TR2, S_TR4, and S_TR6 may be electrically connected to the second gate line GL2 and turned on upon receiving the gate signal provided from the second gate line GL2. Since switching operations of the second, fourth, and sixth driving transistors TR2, TR4, and TR6 correspond to switching operations of the second, fourth, and sixth switching transistors S_TR2, S_TR4, and S_TR6 in one-to-one correspondence, operations of the second red color pixel R2, the second green color pixel G2, and the second blue color pixel B2 may be controlled by the gate signal transmitted through the second gate line GL2.

Similar to the color pixels arranged in the first row, the first red color pixel R1, the first green color pixel G1, and the first blue color pixel B1, which are arranged in a second row, may be controlled by the gate signal transmitted through the third gate line GL3, and the second red color pixel R2, the second green color pixel G2, and the second blue color pixel B2, which are arranged in the second row, may be controlled by the gate signal transmitted through the fourth gate line GL4. In addition, the first red color pixel R1, the first green color pixel G1, and the first blue color pixel B1, which are arranged in a third row, may be controlled by the gate signal transmitted through the fifth gate line GL5, and the second red color pixel R2, the second green color pixel G2, and the second blue color pixel B2, which are arranged in the third row, may be controlled by the gate signal transmitted through the sixth gate line GL6.

In the OLED 500 having the above stated structure, the first red color pixels R1 and the second red color pixels R2 may be separately operated, the first green color pixels G1 and the second green color pixels G2 may be separately operated, and the first blue color pixels B1 and the second blue color pixels B2 may be separately operated.

Thus, when the OLED 500 displays a first image by operating the first red color pixels R1, the first green color pixels G1, and the first blue color pixels B1 that generate the lights transmitted approximately in the third direction D3 (shown in FIG. 4), the OLED 500 may substantially simultaneously display a second image different from the first image by operating the second red color pixels R2, the second green color pixels G2, and the second blue color pixels B2 that generate the lights transmitted approximately in the fourth direction D4 (shown in FIG. 4).

Also, since the first red color pixels R1, the first green color pixels G1, and the first blue color pixels B1 may be separately operated from the second red color pixels R2, the second green color pixels G2, and the second blue color pixels B2, the OLED 500 may substantially simultaneously display the first image and the second image, or the OLED 500 may display either the first image or the second image.

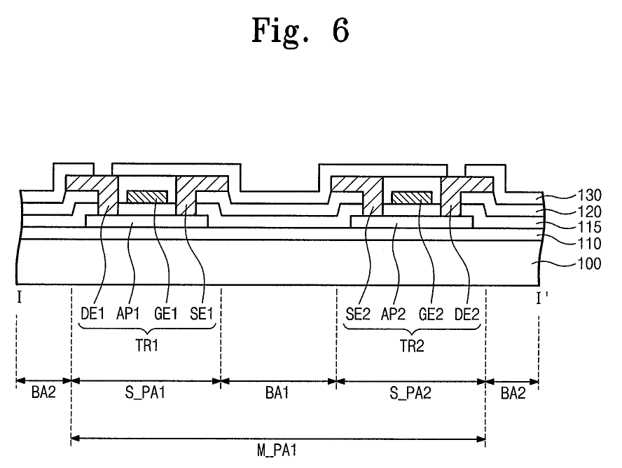

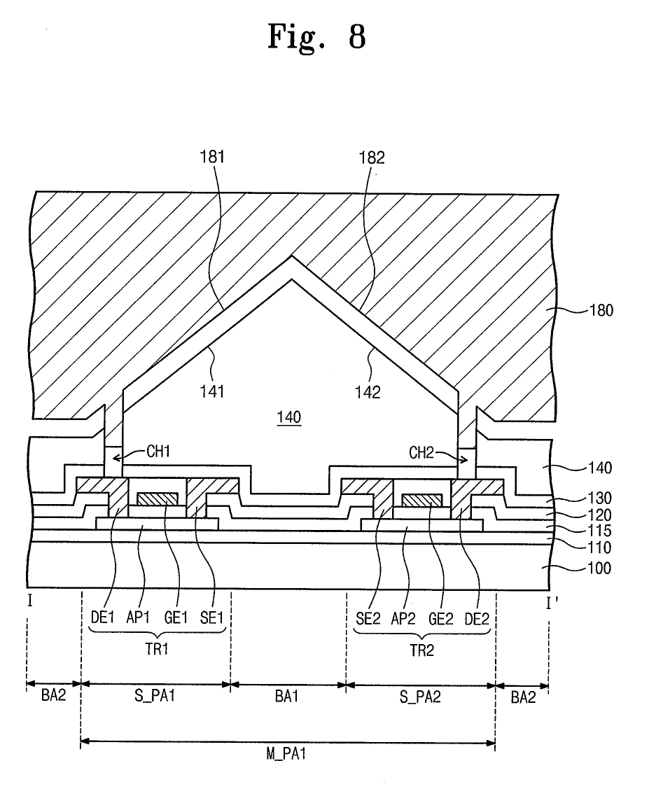

FIGS. 6 to 8 are sectional views showing an a manufacturing method of the organic light emitting display of FIG. 3 in accordance with one or more embodiments.

Referring to FIGS. 6 to 8, the first driving transistor TR1 and the second driving transistor TR2 may be formed on the first substrate 100 on which the blocking layer 110 is formed, and the protective layer 130 may be formed to cover the first and second driving transistors TR1 and TR2. The protective layer 130 may be partially removed to expose the first and second drain electrodes DEI and DE2.

An insulating layer 145 may be formed on the protective layer 130. The insulating layer 145 may include a photoresist material that may be cured by light or heat. After forming the insulating layer 145 on the protective layer 130, the insulating layer 145 may be pressed using a mold 180, and the pressed insulating layer 145 may be cured by heat or light to form the insulating layer pattern 140.

The mold 180 may have a shape corresponding to the insulating layer pattern 140. For example, the mold 180 may include a first press surface 181 and a second press surface 182 corresponding to the first and second inclined surfaces 141 and 142 of the insulating layer pattern 140, respectively. The mold 180 may be formed by transferring a pattern formed on a metallic pattern mold corresponding to the insulating layer pattern 140 onto a surface of the mold 180.

Referring again to FIG. 3, after forming the insulating layer pattern 140, the first and second positive electrodes AE1 and AE2, the first and second organic light emitting layers EL1 and EL2, and the negative electrode CE may be formed to complete the display substrate 200. After completing the display substrate 200, the light blocking layers including the first light blocking layer BM1 may be formed on the second substrate 300 to complete the opposite substrate 400, and then the display substrate 200 and the opposite substrate 400 may be coupled with each other to complete the OLED 500.

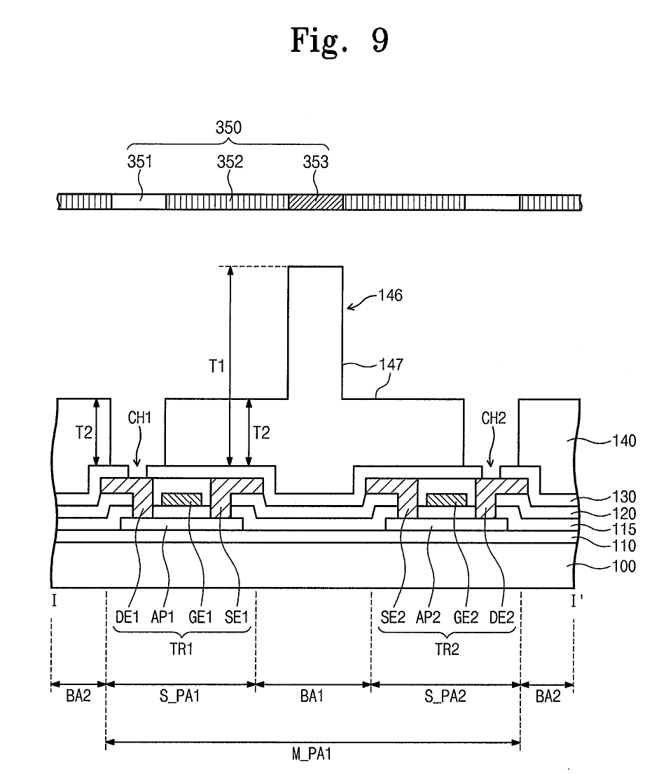

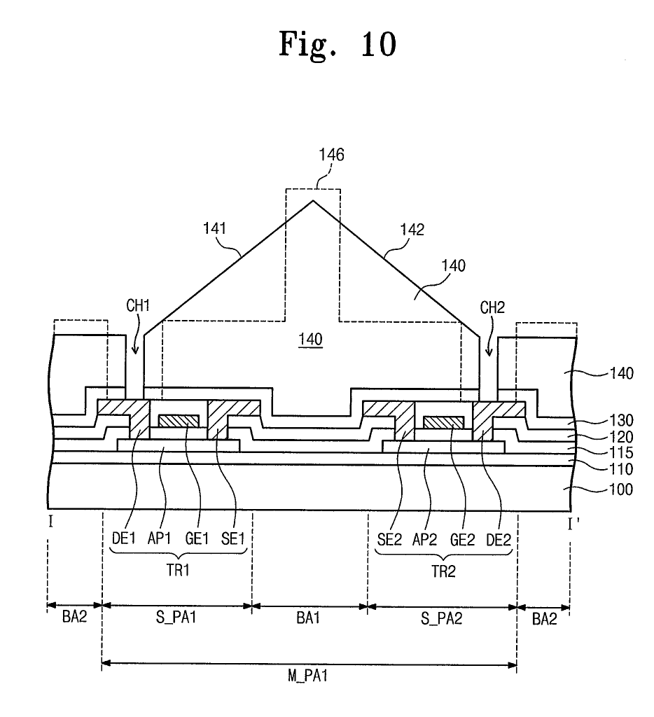

FIGS. 9 and 10 are sectional views showing a manufacturing method of the organic light emitting display of FIG. 3 in accordance with one or more embodiments.

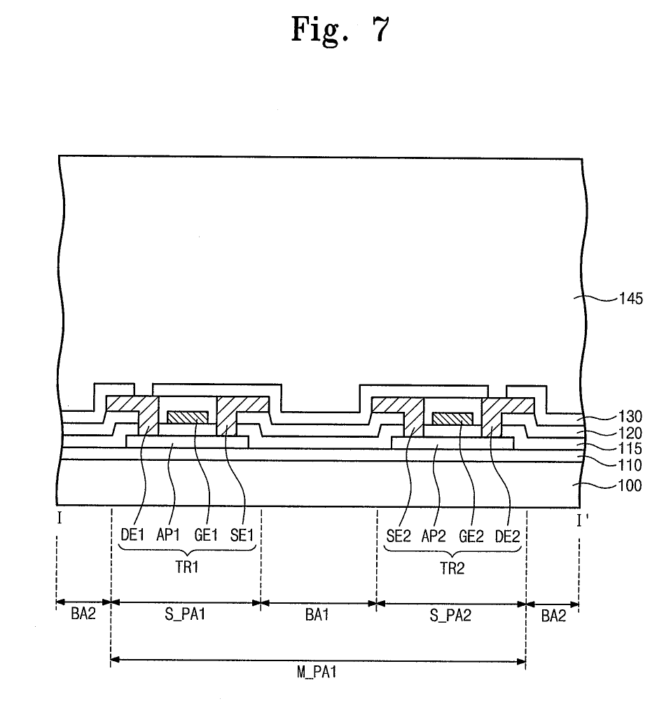

Referring to FIGS. 7 and 9, the insulating layer 145 including a positive photoresist material may be formed on the protective layer 130. The insulating layer 145 may be exposed to a light using a slit mask 350 and developed to form a preliminary insulating layer pattern 146.

The slit mask 350 may include a transmission region 351, a semi-transmission region 352, and a non-transmission region 353. When exposing the insulating layer 145 to the light using the slit mask 350, the non-transmission region 353 may partially overlap the first boundary area BA1, the transmission region 351 may overlap the first and second contact holes CH1 and CH2, and the semi-transmission region 353 may partially overlap the first and second sub-pixel areas S_PA1 and S_PA2.

When the insulating layer 145 is exposed to the light using the slit mask 350 and developed to form the preliminary insulating layer pattern 146, the preliminary insulating layer pattern 146 may have a first thickness T1 corresponding to the non-transmission region 353 and may have a second thickness T2, which may be thinner than the first thickness T1, corresponding to the semi-transmission region 353. Also, the preliminary insulating layer pattern 146 may have an opening corresponding to the transmission region 351. Thus, the preliminary insulating layer pattern 146 may have a step difference portion 147 corresponding to each of the first and second sub-pixel areas S_PA1 and S_PA2.

Referring to FIG. 10, the preliminary insulating layer pattern 146 may be reflowed using a heat process to form the insulating layer pattern 140. As the preliminary insulating layer pattern 146 is reflowed, the step difference portion 147 (shown in FIG. 9) of the preliminary insulating layer pattern 146 may form the first and second inclined surfaces 141 and 142 having an inclination angle with respect to the first substrate 100.

According to the above, the organic light emitting display may display a plurality of images using lights that are transmitted in different directions corresponding to the respective inclined surfaces.

Although the example embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. An organic light emitting display comprising:
a first substrate including a plurality of main-pixel areas each of which includes a plurality of sub-pixel areas;
an insulating layer pattern arranged on the first substrate, the insulating layer pattern including an inclined surface having an inclination angle with respect to the first substrate and corresponding to each sub-pixel area;
a first electrode arranged on the inclined surface;
an organic light emitting layer arranged on the first electrode; and
a second electrode arranged on the organic light emitting layer.

2. The organic light emitting display of claim 1, wherein each of the main-pixel areas comprises:
a first sub-pixel area;
a first boundary area; and
a second sub-pixel area spaced apart from the first sub-pixel area, wherein the first boundary area is interposed between the first and second sub-pixel areas, and
wherein the insulating layer pattern comprises:
a first inclined surface positioned in the first sub-pixel area; and
a second inclined surface positioned in the second sub-pixel area and inclined in a direction different from the first inclined surface.

3. The organic light emitting display of claim 2, wherein a light generated from the organic light emitting layer in the first sub-pixel area has a same color as a light generated from the organic light emitting layer in the second sub-pixel area.

4. The organic light emitting display of claim 2, wherein an inclination angle between the first inclined surface and the first substrate is from about 10 degrees to about 80 degrees.

5. The organic light emitting display of claim 4, wherein an inclination angle between the second inclined surface and the first substrate is from about 100 degrees to about 170 degrees.

6. The organic light emitting display of claim 2, wherein each of the first and second inclined surfaces is inclined in a direction away from the first boundary area.

7. The organic light emitting display of claim 6, wherein each of the first and second sub-pixel areas has a rectangular shape of which sides extend in a first direction and a second direction substantially perpendicular to the first direction, and the first boundary area extends in the first direction or the second direction.

8. The organic light emitting display of claim 7, wherein the main-pixel areas are arranged in the first direction and the second direction, and the first boundary area of each of the main-pixel areas extends in the same direction.

9. The organic light emitting display of claim 7, wherein the first boundary area extends in the second direction, two adjacent main-pixel areas in the first direction are spaced apart from each other, wherein a second boundary area is interposed between the two adjacent main-pixel areas, the insulating layer pattern has a mountain shape corresponding to the first boundary area, and the insulating layer pattern has a valley shape corresponding to the second boundary area.

10. The organic light emitting display of claim 2, further comprising:
a second substrate facing the first substrate; and
a light blocking layer arranged on the second substrate and overlapping the first boundary area to block light.

11. The organic light emitting display of claim 10, wherein the light blocking layer blocks a portion of light generated from the organic light emitting layer arranged in the first sub-pixel area and a portion of light generated from the organic light emitting layer arranged in the second sub-pixel area.

12. The organic light emitting display of claim 10, wherein the light blocking layer extends in the same direction as the first boundary area in a plan view.

13. The organic light emitting display of claim 2, further comprising:
a power supply line arranged on the first substrate and electrically connected to the first electrode to provide a power voltage to the first electrode;
a driving transistor arranged on the first substrate corresponding to the first and second sub-pixel areas to switch the power voltage;
a switching transistor electrically connected to the driving transistor to switch an operation of the driving transistor; and
a gate line electrically connected to the switching transistor to transmit a gate signal that turns on the switching transistor.

14. The organic light emitting display of claim 13, wherein the gate line comprises:
a first gate line that applies the gate signal to the switching transistor arranged in the first sub-pixel area; and
a second gate line that applies the gate signal to the switching transistor arranged in the second sub-pixel area.

15. The organic light emitting display of claim 10, wherein light generated from the organic light emitting layer exits to an upper portion of the second substrate after passing through the second electrode.

16. The organic light emitting display of claim 15, wherein an amount of the light emitted from the organic light emitting layer increases as an angle between the inclined surface and a direction in which the light advances is closer to a right angle with respect to the inclined surface.

17. A method of manufacturing an organic light emitting display, comprising:
preparing a first substrate including a plurality of main-pixel areas each of which includes a plurality of sub-pixel areas;
forming an insulating layer pattern on the first substrate, the insulating layer pattern having an inclined surface inclined with respect to the first substrate to correspond to each of the sub-pixel areas;
forming a first electrode on the inclined surface;
forming an organic light emitting layer on the first electrode; and
forming a second electrode on the organic light emitting layer.

18. The method of claim 17, wherein the forming of the insulating layer pattern comprises:
forming an insulating layer on the first substrate;
pressing the insulating layer using a mold having a press surface corresponding to the inclined surface; and
curing the pressed insulating layer.

19. The method of claim 17, wherein the forming of the insulating layer pattern comprises:
forming an insulating layer having a photosensitive material on the first substrate;
exposing the insulating-layer to a light using a slit mask;
developing the exposed insulating layer to form a preliminary insulating layer pattern having a step difference portion corresponding to each sub-pixel area; and
reflowing the preliminary insulating layer pattern,
wherein the inclined surface of the insulating layer pattern is formed corresponding to the step difference portion by the reflow.

20. The method of claim 17, further comprising:
forming a light blocking layer on a second substrate to block a portion of a light emitted from the organic light emitting layer; and
coupling the second substrate on which the light blocking layer is formed with the first substrate.
